(19) United States
(12) Patent Application Publication
(10) Pub. No.: US 2013/0169113 A1
(43) Pub. Date: Jul. 4, 2013

(54) INERTIAL SENSOR AND METHOD OF MANUFACTURING THE SAME

(71) Applicants: Seung Mo Lim, Gyunggi-do (KR); Yun Sung KANG, Gyunggi-do (KR); Sung Jun LEE, Gyunggi-do (KR); Sang Jin KIM, Gyunggi-do (KR); Jung Won LEE, Seoul (KR); Kyo Yeol LEE, Gyunggi-do (KR)

(72) Inventors: Seung Mo Lim, Gyunggi-do (KR); Yun Sung KANG, Gyunggi-do (KR); Sung Jun LEE, Gyunggi-do (KR); Sang Jin KIM, Gyunggi-do (KR); Jung Won LEE, Seoul (KR); Kyo Yeol LEE, Gyunggi-do (KR)

(73) Assignee: SAMSUNG ELECTRO-MECHANICS CO., LTD., Gyunggi-do (KR)

(21) Appl. No.: 13/468,441

(22) Filed: May 10, 2012

(30) Foreign Application Priority Data
Dec. 29, 2011 (KR) 1020110146075

(51) Int. Cl. H01L 41/047; H01L 41/22

(52) U.S. Cl. 310/329; 29/25.35

(57) ABSTRACT

Disclosed herein are an inertial sensor and a method of manufacturing the same. The inertial sensor 100 according to a preferred embodiment of the present invention may include a membrane 110, a piezoelectric body 130 formed over the membrane 110, an electrode 140 formed on the piezoelectric body 130, a first pad 150 electrically connected with the electrode 140, a second pad 160 electrically connected with an integrated circuit 170, and a connection member 180 electrically connecting the first pad 150 with the second pad 160.

### CROSS REFERENCE TO RELATED APPLICATION

This application claims the benefit of Korean Patent Application No. 10-2011-0146075, filed on Dec. 29, 2011, entitled “Inertial Sensor and Method of Manufacturing the Same”, which is hereby incorporated by reference in its entirety into this application.

### BACKGROUND OF THE INVENTION

1. Technical Field

The present invention relates to an inertial sensor and a method of manufacturing the same.

2. Description of the Related Art

Recently, an inertial sensor has been used in various fields, for example, the military, such as an artificial satellite, a missile, an unmanned aircraft, or the like, vehicles, such as an air bag, electronic stability control (ESC), a black box for a vehicle, or the like, hand shaking prevention of a camcorder, motion sensing of a mobile phone or a game machine, navigation, or the like.

The inertial sensor generally adopts a configuration in which a mass body is bonded to a flexible substrate such as a membrane, or the like, so as to measure acceleration and angular velocity. Through the configuration, the inertial sensor may calculate the acceleration by measuring inertial force applied to the mass body and may calculate the angular velocity by measuring Coriolis force applied to the mass body.

In detail, a scheme of measuring the acceleration and the angular velocity using the inertial sensor is as follows. First, the acceleration may be obtained by Newton's law of motion “F=ma”, where “F” represents inertial force applied to the mass body, “m” represents a mass of the mass body, and “a” is acceleration to be measured. Among others, the acceleration a may be obtained by sensing the inertial force F applied to the mass body and dividing the measured inertial force F by the mass m of the mass body that is a predetermined value. Meanwhile, the angular velocity may be obtained by Coriolis force “F=2mΩ·v”, where “F” represents the Coriolis force applied to the mass body, “m” represents the mass of the mass body, “Ω” represents the angular velocity to be measured, and “v” represents the motion velocity of the mass body. Among others, since the motion velocity v of the mass body and the mass m of the mass body are values that are known in advance, the angular velocity may be obtained by sensing the Coriolis force (F) applied to the mass body.

Meanwhile, an inertial sensor according to the prior art includes a piezoelectric body provided on an upper portion of a membrane(diaphragm) in order to drive a mass body as disclosed in Korean Patent Laid-Open Publication No. 10-2011-0072229. Herein, piezoelectric characteristics of the piezoelectric body may be increased through poling applying voltage. However, since relatively higher voltage is applied at the time of poling, when the poling is performed after an integrated circuit (IC) is connected with the inertial sensor, elements in the integrated circuit may be destructed due to the high voltage applied at the time of the poling.

Generally, in order to solve the above problems, the integrated circuit is connected with the inertial sensor after poling the piezoelectric body. However, when the integrated circuit is connected with the inertial sensor by a wire bonding, the piezoelectric body is applied with high heat due to the wire bonding, such that the poling may be released while a piezoelectric deterioration phenomenon occurring in the piezoelectric body.

### SUMMARY OF THE INVENTION

The present invention has been made in an effort to provide an inertial sensor and a method of manufacturing the same capable of preventing elements in an integrated circuit from being destructed due to high voltage applied at the time of poling even when poling the piezoelectric body after connecting an integrated circuit, by separately providing pads for poling the piezoelectric body in addition to pads electrically connected with the integrated circuit.

According to a preferred embodiment of the present invention, there is provided an inertial sensor, including: a membrane; a piezoelectric formed over the membrane; an electrode formed on the piezoelectric body; a first pad electrically connected with the electrode; a second pad electrically connected with an integrated circuit; and a connection member electrically connecting the first pad with the second pad.

The piezoelectric may be poled by applying voltage to the first pad.

The second pad may be electrically connected with the integrated circuit through a wire bonding.

The electrode may include: a first electrode formed on one surface of the piezoelectric body; and a second electrode formed on the other surface of the piezoelectric body.

The first pad may be formed on one surface of the piezoelectric body, and the first pad may be electrically connected with the first electrode through a first wiring and may be electrically connected with the second electrode through a via penetrating through the piezoelectric body.

The connection member may be a conductive paste.

The inertial sensor may further include a third pad electrically connected with the second pad through a second wiring, wherein the connection member is a conductive paste electrically connecting the first pad with the third pad.

When the piezoelectric body is partitioned into an inner annular region surrounding a center of the piezoelectric body and an outer annular region surrounding the inner annular region, the first electrode may include: driving electrodes patterned in an arc divided into N in the inner annular region; and sensing electrodes patterned in an arc divided into M in the outer annular region.

When the piezoelectric body is partitioned into an inner annular region surrounding a center of the piezoelectric body and an outer annular region surrounding the inner annular region, the first electrode may include: sensing electrodes patterned in an arc divided into N in the inner annular region; and driving electrodes patterned in an arc divided into M in the outer annular region.

The inertial sensor may further include: a mass body provided under a central portion of the membrane; and posts provided under edges of the membrane.

According to another preferred embodiment of the present invention, there is provided a method of manufacturing an inertial sensor, including: (A) preparing a basic member including a membrane, a piezoelectric body formed over the membrane, an electrode formed on the piezoelectric body, and a first pad and a second pad electrically connected with the electrode; (B) poling the piezoelectric body by applying voltage to the first pad after electrically connecting the second pad with an integrated circuit; and (C) electrically connecting the first pad with the second pad by a connection member.

At step (B), the second pad may be electrically connected with the integrated circuit through a wire bonding

At step (A), the electrode may include: a first electrode formed on one surface of the piezoelectric body; and a second electrode formed on the other surface of the piezoelectric body.

At step (A), the first pad may be formed on one surface of the piezoelectric body, and the first pad may be electrically connected with the first electrode through a first wiring and may be electrically connected with the second electrode through a via penetrating through the piezoelectric body.

At step (C), the connection member may be a conductive paste.

At step (A), the basic member may further include a third pad electrically connected with the second pad through a second wiring, and at step (C), the connection member may be a conductive paste electrically connecting the first pad with the third pad.

When the piezoelectric body is partitioned into an inner annular region surrounding a center of the piezoelectric body and an outer annular region surrounding the inner annular region, the first electrode may include: driving electrodes patterned in an arc divided into N in the inner annular region; and sensing electrodes patterned in an arc divided into M in the outer annular region.

When the piezoelectric body is partitioned into an inner annular region surrounding a center of the piezoelectric body and an outer annular region surrounding the inner annular region, the first electrode may include: sensing electrodes patterned in an arc divided into N in the inner annular region; and driving electrodes patterned in an arc divided into M in the outer annular region.

At step (A), the basic member may include: a mass body provided under a central portion of the membrane; and posts provided under edges of the membrane.

### BRIEF DESCRIPTION OF THE DRAWINGS

FIG. 1 is a perspective view of an inertial sensor according to a preferred embodiment of the present invention;

FIG. 2 is a cross-sectional view of the inertial sensor shown in FIG. 1;

FIG. 3 is a perspective view of a modified example of the inertial sensor according to the preferred embodiment of the present invention;

FIG. 4 is a perspective view of an inertial sensor according to another preferred embodiment of the present invention;

FIG. 5 is a cross-sectional view of the inertial sensor shown in FIG. 4;

FIGS. 6 to 9 are plan views and cross-sectional views sequentially showing a process of a method of manufacturing an inertial sensor according to a preferred embodiment of the present invention;

FIG. 10 is a diagram for explaining a process of poling the piezoelectric body; and

FIGS. 11 to 14 are plan views sequentially showing a process of a method of manufacturing an inertial sensor according to another preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. Further, in describing the present invention, a detailed description of related known functions or configurations will be omitted so as not to obscure the subject of the present invention.

Hereinafter, preferred embodiments of the present invention will be described in detail with reference to the accompanying drawings.

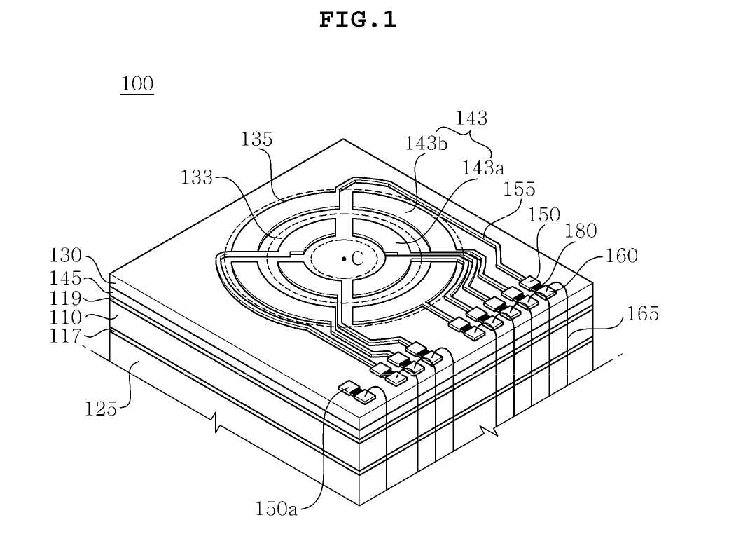

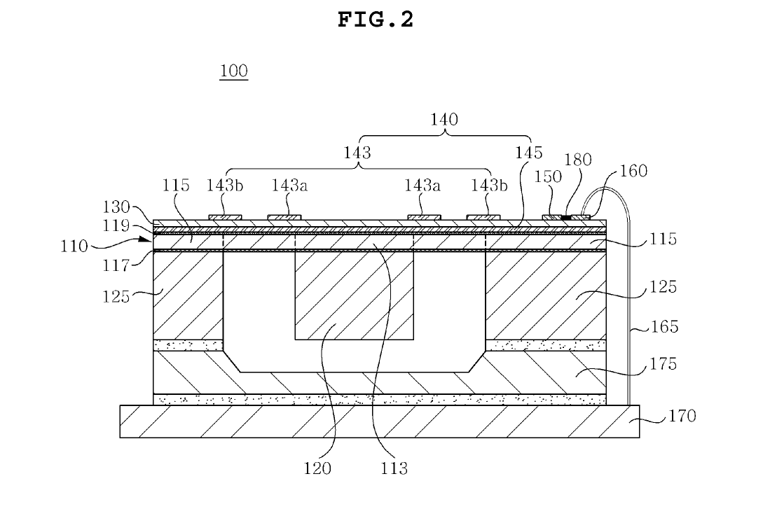

FIG. 1 is a perspective view of an inertial sensor according to a preferred embodiment of the present invention and FIG. 2 is a cross-sectional view of the inertial sensor shown in FIG. 1.

As shown in FIGS. 1 and 2, an inertial sensor 100 according to a preferred embodiment of the present invention may include a membrane 110, a piezoelectric body 130 formed over the membrane 110, an electrode 140 formed on the piezoelectric body 130, a first pad 150 electrically connected with the electrode 140, a second pad 160 electrically connected with an integrated circuit 170, and a connection member 180 electrically connecting the first pad 150 with the second pad 160.

The membrane 110 is formed in a plate shape to thereby have elasticity so that the mass body 120 may be displaced. Herein, a boundary of the membrane 110 is not accurately differentiated, but may be partitioned into a central portion 113 of the membrane 110 and edges 115 provided along an outside of the membrane 110, as shown. In this case, the mass body 120 may be provided under the central portion 113 of the membrane 110 and posts 125 may be provided under the edges 115 of the membrane 110. Therefore, the edges 115 of the membrane 110 are fixed by being supported by the posts 125, and displacement corresponding to movement of the mass body 120 is generated at the central portion 113 of the membrane 110 based on the fixed edges 115 of the membrane 110.

More specifically, describing the mass body 120 and the posts 125, the mass body 120 is provided under the central portion 113 of the membrane 110 to thereby be displaced by inertial force or Coriolis force. In addition, the posts 125 are formed in a hollow shape to support the lower portions of the edges 115 of the membrane 110 to thereby serve to secure a space in which the mass body 120 may be displaced. Here, the mass body 120 may be formed in, for example, a cylindrical shape and the posts 125 may be formed in a square pillar shape in which a cavity having a cylindrical shape is formed at a center thereof. That is, when being viewed from a transverse section, the mass body 120 is formed in a circular shape and the posts 125 are formed in a square shape having a circular opening provided at the center thereof. However, the shape of the mass body 120 and the posts 125 is not limited thereto, but may be all shapes known in the art.

Meanwhile, the above-mentioned membrane 110, mass body 120, and posts 125 may be formed by selectively etching a silicon on insulator (SOI) substrate to which a micro electromechanical systems (MEMS) process is easily applied. Therefore, a silicon oxide film (SiO₂) 117 of the SOI substrate may remain between the mass body 120 and the membrane 110 and between the posts 125 and the membrane 110. However, the membrane 110, the mass body 120, and the posts 125 do not need to be formed by etching the SOI substrate but may be formed by etching a general silicon substrate, or the like.

The piezoelectric body 130 and the electrode 140 serve to drive the mass body 120 or sense the displacement of the mass body 120 Here, the piezoelectric body 130 may be formed over the membrane 110 by using lead zirconate titanate (PZT), barium titanate (BaTiO₃), lead titanate (PbTiO₃), lithium niobate (LiNbO₃), silicon dioxide (SiO₂), or the like. Further, the electrode 140 includes a first electrode 143 formed on one surface of the piezoelectric body 130 and a second electrode 145 formed on the other surface of the piezoelectric body 130. More specifically, when voltage is applied to the piezoelectric body 120 through the first electrode 143 and the second electrode 145, an inverse piezoelectric effect that expands and contracts the piezoelectric body 130 is generated. The mass body 120 formed under the membrane 110 may be driven using the inverse piezoelectric effect. On the other hand, when stress is applied to the piezoelectric element 130, a piezoelectric effect that a potential difference between the first electrode 143 and the second electrode 145 appears is generated. This piezoelectric effect is used, thereby making it possible to sense the displacement of the mass body 120 provided under the membrane 110.

In order to use the inverse piezoelectric effect and the piezoelectric effect of the piezoelectric body 130, one surface of the piezoelectric body 130 may be patterned with a plurality of first electrodes 143 and a bottom surface of the piezoelectric body 130 may be formed with the second electrode 145 as common electrode. Herein, in order to insulate the second electrode 145 and the membrane 110, an insulating layer 119 of a silicon oxide film, or the like, may be formed between the second electrode 145 and the membrane 110. In describing in more detail the first electrode 143 patterned in plural, the first electrode 143 may be patterned in eight and the eight first electrodes 143 may be configured of sensing electrodes 143b using the piezoelectric effect and driving electrodes 143a using the inverse piezoelectric effect. In this case, the driving electrodes 143a and the sensing electrodes 143b configuring the first electrode 143 are each formed in an arc. For example, when the piezoelectric body 130 is partitioned into an inner annular region 133 surrounding a center C of the piezoelectric body 130 and an outer annular region 135 surrounding the inner annular region 133, the inner annular region 133 may be patterned with driving electrodes 143a in an arc divided into N (N is a natural number, four in the drawings) and the outer annular region 135 may be patterned with the sensing electrodes 143b in an arc divided into M (M is a natural number, four in the drawings).

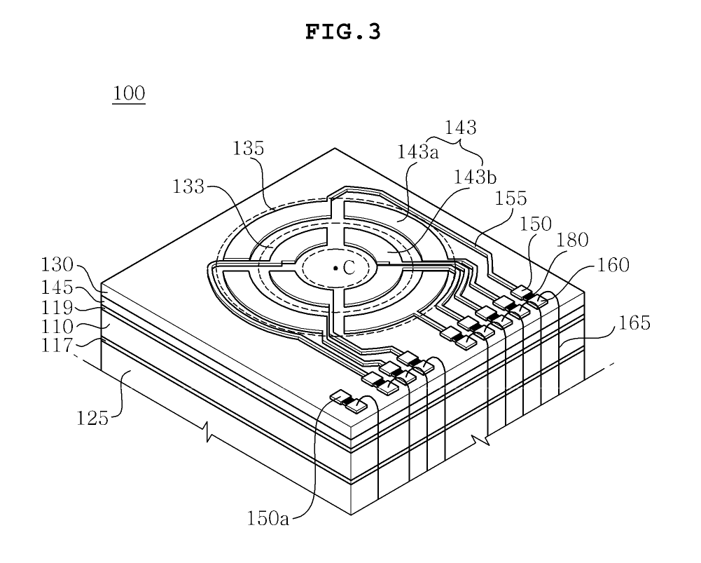

Meanwhile, FIG. 3 is a perspective view of a modified example of the inertial sensor according to the preferred embodiment of the present invention and as shown in FIG. 3, the position of the driving electrode 143a and the sensing electrode 143b may be may be changed from each other. For example, when the piezoelectric body 130 is partitioned into an inner annular region 133 surrounding a center C of the piezoelectric body 130 and an outer annular region 135 surrounding the inner annular region 133, the inner annular region 133 may be patterned with the sensing electrodes 143b in an arc divided into N (N is a natural number, four in the drawings) and the outer annular region 135 may be patterned with the driving electrodes 143a in an arc divided into M (M is a natural number, four in the drawings).

However, the number of patterned first electrodes 143 and the position of the driving electrode 143a and the sensing electrode 143b are not limited to the above-mentioned configuration and may be variously changed. In addition, although the second electrode 145 is formed as the common electrode without being patterned in drawings, the scope of the present invention is not limited thereto and the second electrode 145 may be patterned to correspond to the first electrode 143. Further, when the inertial sensor 100 is used as an acceleration sensor, there is no need to drive the mass body 120. Therefore, the driving electrode 143a may be omitted.

The first pad 150 is applied with voltage when poling the piezoelectric body 130 and is electrically connected with the electrode 140. Herein, the first pad 150 may be formed on one surface of the piezoelectric body 130 to be electrically connected with the first electrode 143 through a first wiring 155 and a portion of the first pad 150a may be electrically connected with the second electrode 145 through a via penetrating through the piezoelectric body 130. Therefore, the first pad 150 may be formed in a number corresponding to the first electrode 143 and the second electrode 145. For example, as shown, when the first electrode 143 is patterned in eight and the second electrode 145 is formed in a single common electrode, the first pad 150 is formed in a total of nine. As described above, the first pad 150 is electrically connected with the first electrode 143 and the second electrode 145, when voltage is applied to the first pad 150, voltage is applied to the piezoelectric body 130 through the first electrode 143 and the second electrode 145 and thus, the piezoelectric body 130 is poled. However, when poling the piezoelectric body 130, the first pad 150 is not electrically connected with the second pad 160 that is electrically connected with the integrated circuit 170. Therefore, even though the piezoelectric body 130 is poled by applying voltage to the first pad 150, the voltage is not applied to the integrated circuit 170 through the second pad 160, such that it is possible to prevent the elements in the integrated circuit 170 from being destructed.

The second pad 160 serves to electrically connect the inertial sensor 100 with the integrated circuit 170 and is formed on the piezoelectric body 130. Finally, the second pad 160 is electrically connected with the first pad 150. Therefore, the second pad 160 may be formed in a number corresponding to the first pad 150. For example, as shown in FIG. 1, the first pad 150 is formed in a total of nine and therefore, the second pad 160 may be formed in a total of 9. In addition, the second pad 160 is electrically connected with the first pad 150 through a connection member 180 and therefore, may be formed on one surface of the piezoelectric body 130 so as to be adjacently disposed on the first pad 150, but is not necessarily limited thereto. Meanwhile, the second pad 160 is electrically connected with the integrated circuit 170 by the wire bonding using, for example, a wire 165. Herein, the above-mentioned wire bonding is performed before poling the piezoelectric body 130, such that it is possible to prevent the poling from being released while the piezoelectric deterioration phenomenon occurring in the piezoelectric body 130 due to the high heat caused by the wire bonding. In addition, the integrated circuit 170 electrically connected with the second pad 160 is not particularly thereto but may be a semiconductor such as an application specific integrated circuit (ASIC), or the like. Further, a position of the integrated circuit 170 is not particularly limited thereto, but a lower cap 175 may be attached to a bottom portion of the posts 125.

The connection member 180 serves to electrically connect the first pad 150 with the second pad 160. Here, the connection member 180 is formed after poling the piezoelectric body 130 by applying voltage to the first pad 150 and electrically connects the first pad 150 with the second pad 160. Therefore, the connection member 180 is not formed when poling the piezoelectric body 130 by applying voltage to the first pad 150 and is in a state in which the first pad 150 is not electrically connected with the second pad 160. Therefore, even though the piezoelectric body 130 is poled by applying voltage to the first pad 150, the voltage is not applied to the integrated circuit 170 through the second pad 160, such that it is possible to prevent the elements in the integrated circuit 170 from being destructed. Meanwhile, the connection member 180 may be a conductive paste. As the conductive paste, a silver paste, or the like, may be used. Further, since the connection member 180 is formed after poling the piezoelectric body 130, an ambient temperature curing conductive paste that does not require separate heating may be used so as to prevent the piezoelectric deterioration phenomenon from occurring in the piezoelectric body 130 due to the high heat. However, using the conductive paste as the connection member 180 is an example and therefore, the preferred embodiment of the present invention is not limited thereto. As a result, if the connection member can electrically connect the first pad 150 with the second pad 160, any component may be used as the connection member 180.

As described above, when the first pad 150 is electrically connected with the second pad 160 by the connection member 180, the piezoelectric body 130→the first electrode 143 or the second electrode 145→the first wiring 155 or the via→the first pad 150 the connection member 180→the second pad 160→the wire 165→the integrated circuit 170 are electrically connected with one another in order. Therefore, the integrated circuit 170 is electrically connected with the first electrode 143 or the second electrode 145 through the wire 165→the second pad 160→the connection member 180→the first pad 150→the first wiring 155 or the via to drive the mass body 120 or sense the displacement of the mass body 120.

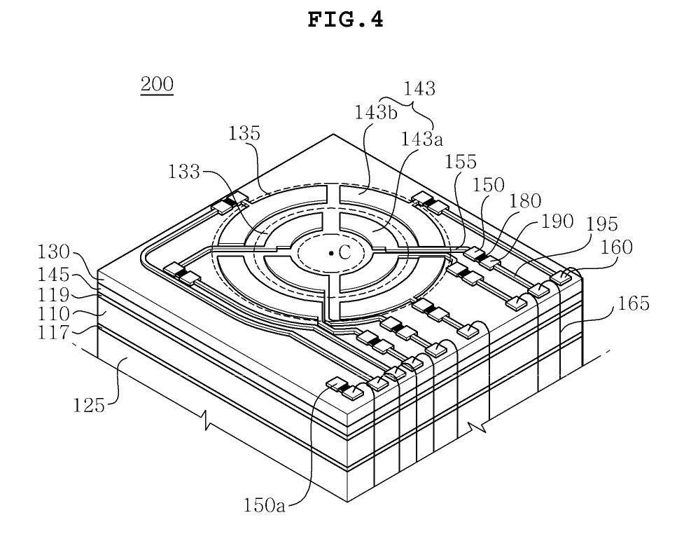

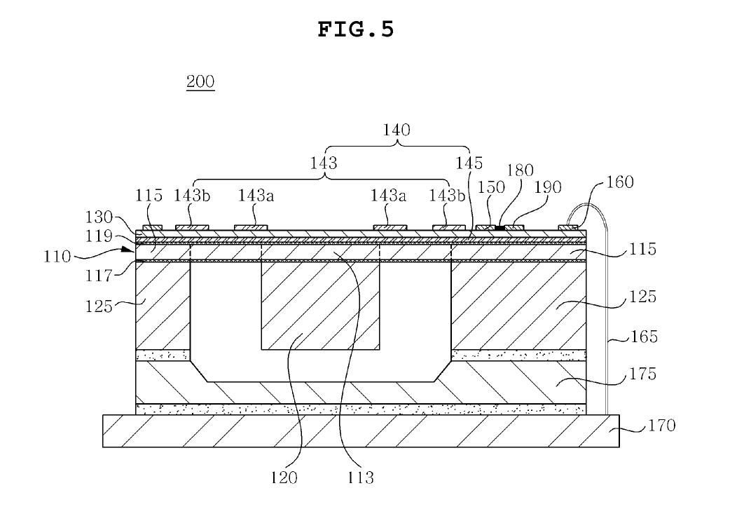

FIG. 4 is a perspective view of an inertial sensor according to another preferred embodiment of the present invention and FIG. 5 is a cross-sectional view of the inertial sensor shown in FIG. 4.

As shown in FIGS. 4 and 5, when an inertial sensor 200 according to a preferred embodiment of the present invention compares with the inertial sensor 100 according to the preferred embodiment of the present invention, the inertial sensor 200 may further include a third pad 190, a second wiring 195, or the like. Therefore, in the preferred embodiment of the present invention, the overlapping contents of the above-mentioned preferred embodiment are omitted and therefore, the third pad 190 and the second wiring 195 will be mainly described.

Finally, the third pad 190 is electrically connected with the first pad 150 through the connection member 180. Therefore, the third pad 190 extends through the second wiring 195 from the second pad 160 and thus, may be formed so as to be adjacent to the first pad 150. In the inertial sensor 200 according to the preferred embodiment of the present invention, when the first pad 150 is electrically connected with the third pad 190 by the connection member 180, the piezoelectric body 130 the first electrode 143 or the second electrode 145→the first wiring 155 or the via the first pad 150→the connection member 180 the third pad 190␣the second wire 195 the second pad 160→the wire 165→the integrated circuit 170 are electrically connected with one another in order. Therefore, the integrated circuit 170 is electrically connected with the first electrode 143 or the second electrode 145 through the wire 165 the second pad 160 the second wiring 195→the third pad 190→the connection member 180→the first pad 150 the first wiring 155 or the via to drive the mass body 120 or sense the displacement of the mass body 120. However, all the first pads 150 are not necessarily connected with the third pad 190 through the connection member 180. For example, a first pad 150a electrically connected with the second electrode 145 may be directly and electrically connected with the second pad 160 without the third pad 190.

Meanwhile, when comparing with the inertial sensor 100 according to the preferred embodiment of the present invention, the inertial sensor 200 according to the preferred embodiment of the present invention further includes the third pad 190 extending through the second wiring 195 from the second pad 160, such that a distance between the first pad 150 and the second pad 160 is far away from each other and a distance between the first pad 150 and the electrode 140 is closed to each other. As a result, the length of the first wiring 155 is relatively shorter.

In addition, similar to the inertial sensor 100 according to the preferred embodiment of the present invention, the inertial sensor 200 according to the preferred embodiment of the present invention poles the piezoelectric body 130 by applying voltage to the first pad 150 and then, electrically connecting the first pad 150 with the third pad 190 by the connection member 180. Therefore, the connection member 180 is not formed when poling the piezoelectric body 130 by applying voltage to the first pad 150 and is in a state in which the first pad 150 is not electrically connected with the third pad 190. Therefore, even though the piezoelectric body 130 is poled by applying voltage to the first pad 150, the voltage is not applied to the integrated circuit 170 through the third pad 190, the second wiring 195, and the second pad 160, such that it is possible to prevent the elements in the integrated circuit 170 from being destructed.

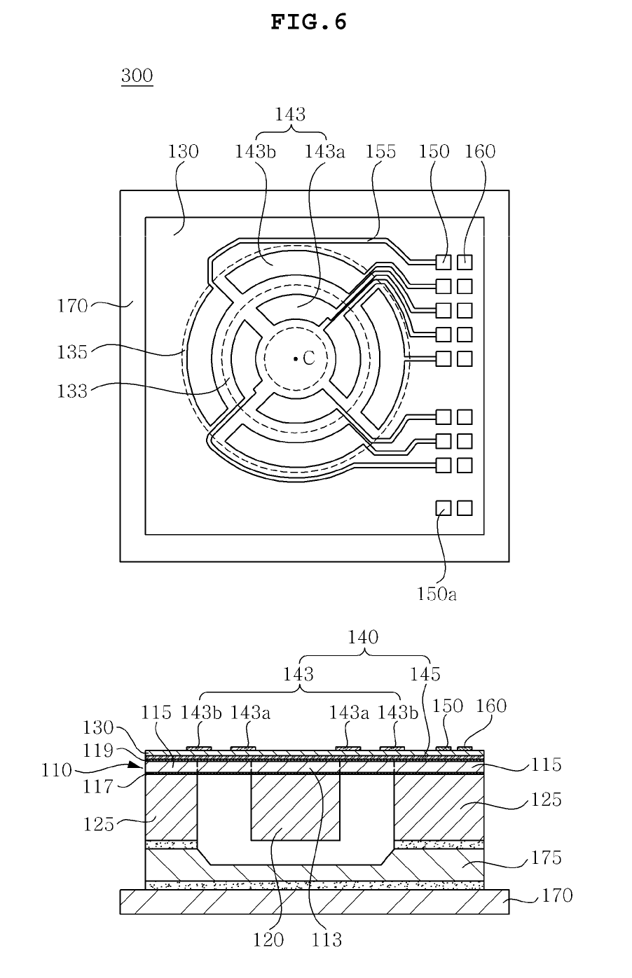

FIGS. 6 to 9 are plan views and cross-sectional views sequentially showing a process of a method of manufacturing an inertial sensor according to a preferred embodiment of the present invention.

As shown in FIGS. 6 to 9, the inertial sensor 100 according to the preferred embodiment of the present invention may include: (A) preparing a basic member 300 including the membrane 110, the piezoelectric body 130 formed over the membrane 110, the electrode 140 formed on the piezoelectric body 130, and the first pad 150 and the second pad 160 electrically connected with the electrode 140, (B) poling the piezoelectric body 130 by applying voltage to the first pad 150 after electrically connecting the second pad 160 with the integrated circuit 170; and (C) electrically connecting the first pad 150 with the second pad 160 by the connection member 180.

First, as shown in FIG. 6, an operation of preparing the basic member 300 is performed. Here, the basic member 300 includes the membrane 110, the piezoelectric body 130 formed over the membrane 110, the electrode 140 formed on the piezoelectric body 130, and the first pad 150 and the second pad 160 electrically connected with the electrode 140 and includes basic components of the inertial sensor 100 other than the connection member 180. In this case, the basic member 300 may further include the mass body 120 provided under the central portion 113 of the membrane 110 and the posts 125 provided under the edges 115 of the membrane 110. Further, the lower cap 175 provided under the posts 125 may be attached with the integrated circuit 170.

More specifically, the electrode 140 of the basic member 300 may include the first electrode 143 formed on one surface of the piezoelectric body 130 and the second electrode 145 formed on the other surface of the piezoelectric body 130. In addition, in order to use the inverse piezoelectric effect and the piezoelectric effect of the piezoelectric body 130 for each region, the first electrode 143 may be patterned in plural. For example, the first electrode 143 may be configured to include the sensing electrodes 143b using the piezoelectric effect and the driving electrodes 143a using the inverse piezoelectric effect. In this case, the driving electrodes 143a and the sensing electrodes 143b configuring the first electrode 143 are each formed in an arc. For example, when the piezoelectric body 130 is partitioned into an inner annular region 133 surrounding the center C of the piezoelectric body 130 and an outer annular region 135 surrounding the inner annular region 133, the inner annular region 133 may be patterned with the driving electrodes 143a in an arc divided into N (N is a natural number, four in the drawings) and the outer annular region 135 may be patterned with the sensing electrodes 143b in an arc divided into M (M is a natural number, four in the drawings).

In addition, the position of the driving electrodes 143a and the sensing electrodes 143b may be changed from each other (see FIG. 3). For example, when the piezoelectric body 130 is partitioned into an inner annular region 133 surrounding the center C of the piezoelectric body 130 and an outer annular region 135 surrounding the inner annular region 133, the inner annular region 133 may be patterned with the sensing electrodes 143b in an arc divided into N (N is a natural number, four in the drawings) and the outer annular region 135 may be patterned with the driving electrodes 143a in an arc divided into M (M is a natural number, four in the drawings).

Meanwhile, the first pad 150 of the basic member 130 is electrically connected with the electrode 140. Herein, the first pad 150 may be formed on one surface of the piezoelectric body 130 to be electrically connected with the first electrode 143 through a first wiring 155 and a portion of the first pad 150a may be electrically connected with the second electrode 145 through a via penetrating through the piezoelectric body 130.

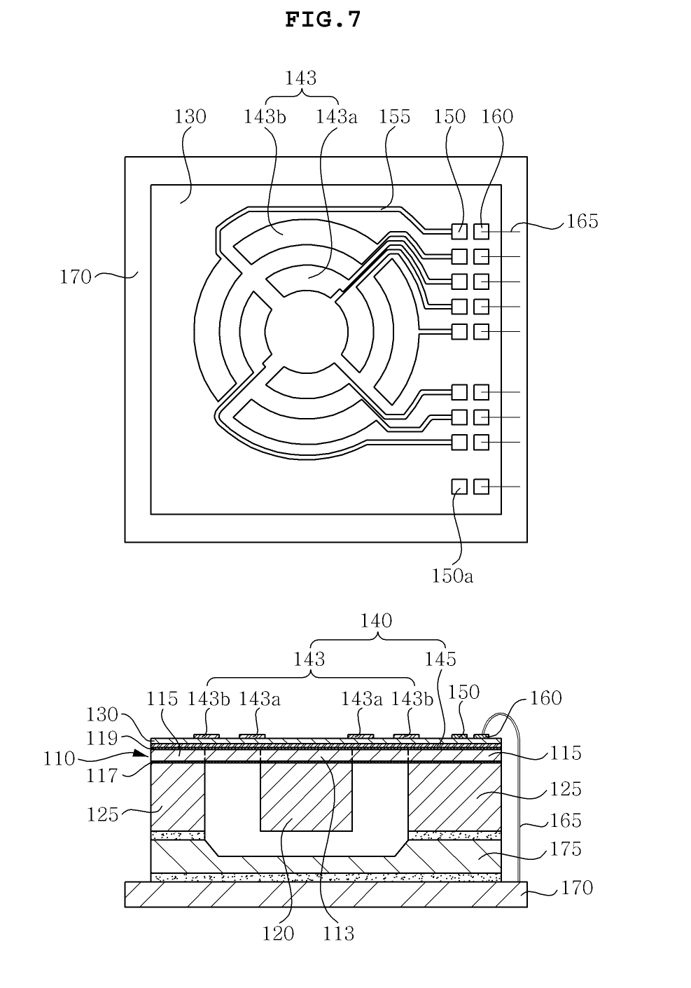

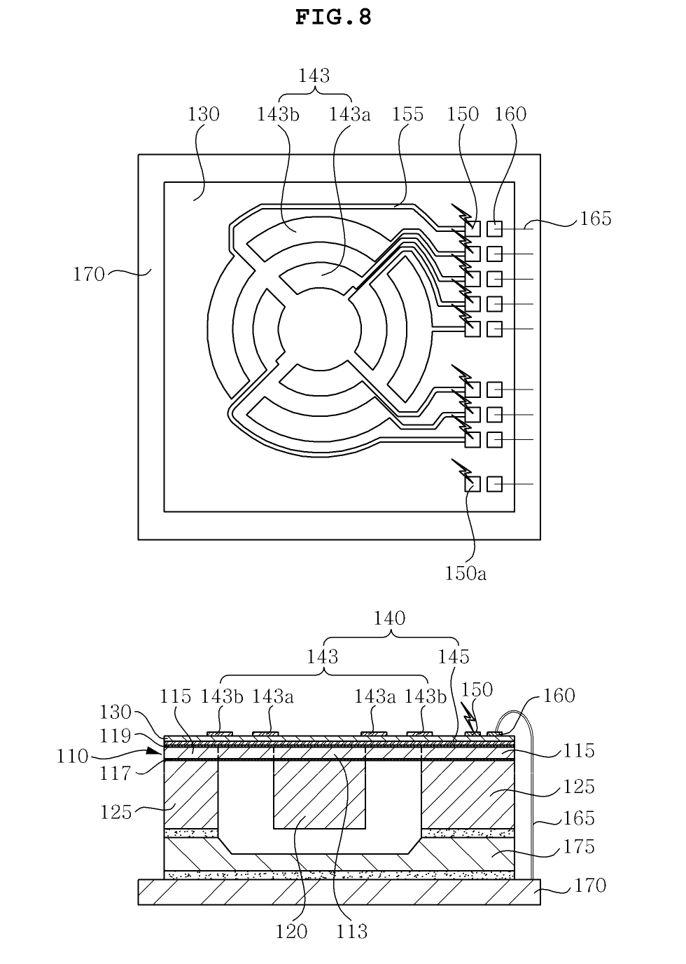

Next, as shown in FIGS. 7 and 8, after the second pad 160 is electrically connected with the integrated circuit 170, the process of poling the piezoelectric body 130 by applying voltage to the first pad 150 is performed. Here, the second pad 160 is electrically connected with the integrated circuit 170 by the wire bonding using, for example, a wire 165 (see FIG. 7). After the second pad 160 is electrically connected with the integrated circuit 170 by the wire bonding, when voltage is applied to the first pad 150, the poling is performed by applying voltage to the piezoelectric body 130 through the first wiring 155, the first electrode 143, and the second electrode 145 (see FIG. 8).

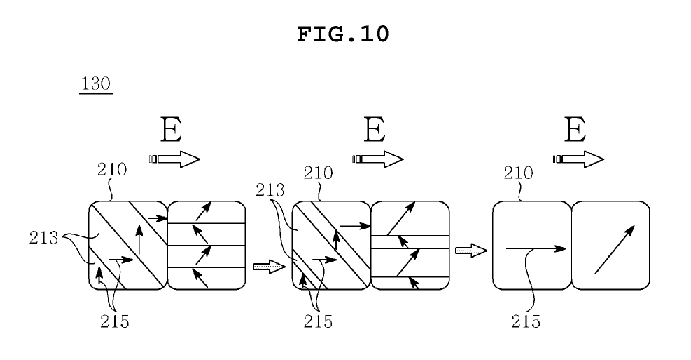

Meanwhile, FIG. 10 is a diagram for explaining the process of poling a piezoelectric body. The process of poling the piezoelectric body 130 will be described with reference to FIG. 10. Domains 213 having dipoles 215 formed in different directions are present within a grain 210 of the piezoelectric body 130 before poling. When voltage is applied to the piezoelectric body 130, electric field E is generated and the directions of the dipoles 215 of the adjacent domains 213 gradually correspond to each other by the electric field E. In addition, the directions of the dipoles 215 of the adjacent grains 210 also correspond or similar to each other.

Meanwhile, the above-mentioned wire bonding generates the high heat, such that the piezoelectric deterioration phenomenon may occur in the piezoelectric body 130. However, the preferred embodiment of the present invention performs the wire bonding (see FIG. 7) and then, poles the piezoelectric body 130. Therefore, it is possible to previously prevent the piezoelectric deterioration phenomenon from occurring in the piezoelectric body 130 due to the high heat caused by the wire bonding.

In addition, when poling the piezoelectric body 130, the first pad 150 is not electrically connected with the second pad 160 that is electrically connected with the integrated circuit 170. Therefore, even though voltage is applied to the first pad 150, the voltage is not applied to the integrated circuit 170 through the second pad 160, such that it is possible to prevent the elements in the integrated circuit 170 from being destructed.

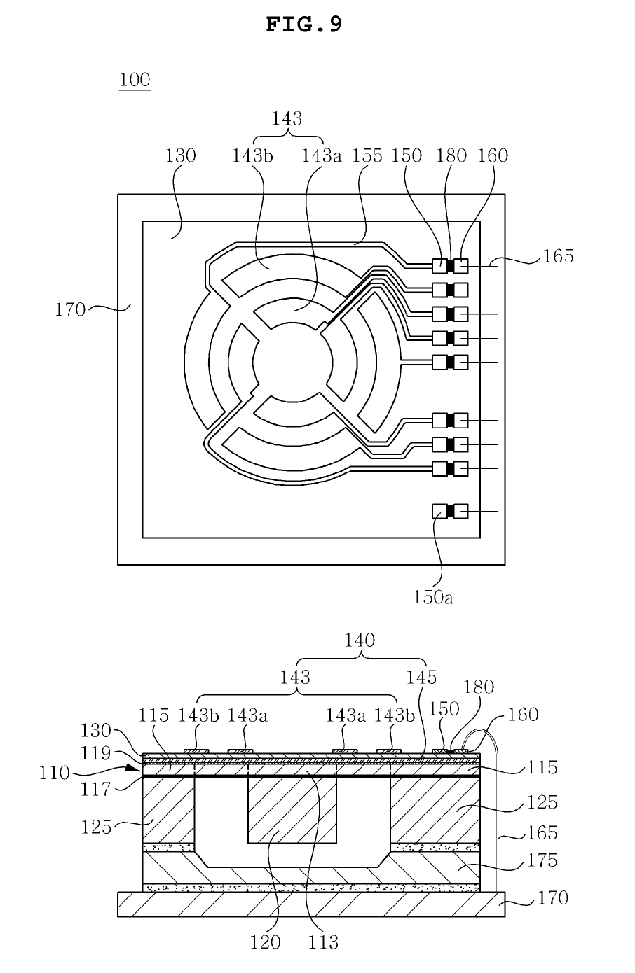

Next, as shown in FIG. 9, a process of connecting the first pad 150 with the second pad 160 by the connection member 180 is performed. Herein, the connection member 180 may be the conductive paste such as the silver paste, or the like. Further, since the connection member 180 is formed after poling the piezoelectric body 130, an ambient temperature curing conductive paste that does not require separate may be used so as to prevent the piezoelectric deterioration phenomenon from occurring in the piezoelectric body 130 due to the high heat. As described above, when the first pad 150 is electrically connected with the second pad 160 by forming the connection member 180, finally, the integrated circuit 170 is electrically connected with the first electrode 143 or the second electrode 145, thereby driving the mass body 120 or sensing the displacement of the mass body 120.

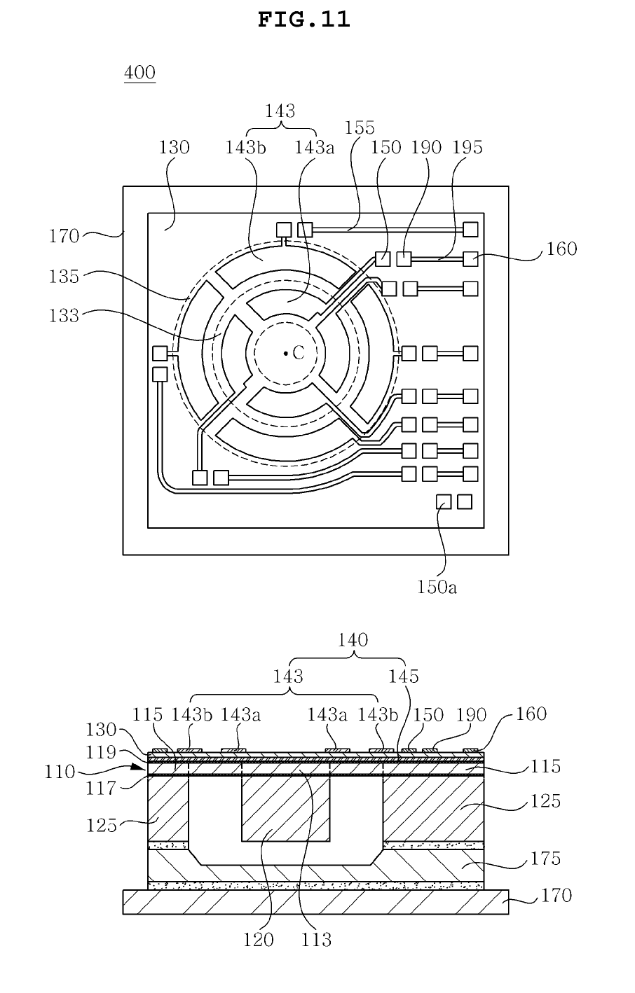

FIGS. 11 to 14 are plan views sequentially showing a process of a method of manufacturing an inertial sensor according to another preferred embodiment of the present invention.

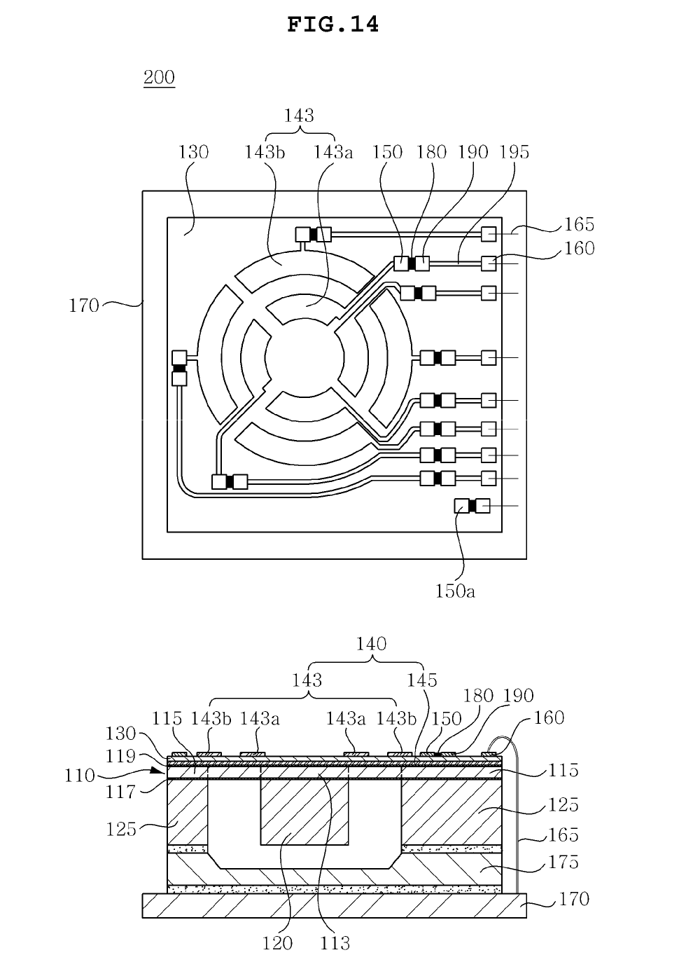

As shown in FIGS. 11 and 14, when an inertial sensor 200 according to a preferred embodiment of the present invention compares with the inertial sensor 100 according to the preferred embodiment of the present invention, the inertial sensor 200 may further include the third pad 190, the second wiring 195, or the like. Therefore, in the preferred embodiment of the present invention, the overlapping contents of the above-mentioned preferred embodiment are omitted and therefore, the third pad 190 and the second wiring 195 will be mainly described.

First, as shown in FIG. 11, an operation of preparing the basic member 400 is performed. Here, the basic member 400 includes the membrane 110, the piezoelectric body 130 formed over the membrane 110, the electrode 140 formed on the piezoelectric body 130, the first pad 150 and the second pad 160 electrically connected with the electrode 140, and the third pad 190 electrically connected with the second pad 160 through the second wiring 195, which includes the basic components of the inertial sensor 200 other than the connection member 180. In this case, the third pad 190 is formed to correspond to the first pad 150, but is not necessarily formed in the number corresponding to the first pad 150. For example, the third pad 190 corresponding to the first pad 150a electrically connected with the second electrode 145 may be omitted.

When comparing with the basic member 300 according to the above-mentioned preferred embodiment of the present invention, in the basic member 400 according to the preferred embodiment of the present invention, the third pad 190 extending through the second wiring 195 from the second pad 160 is added, such that the distance between the first pad 150 and the second pad 160 is far away from each other and the distance between the first pad 150 and the electrode 140 is closed to each other.

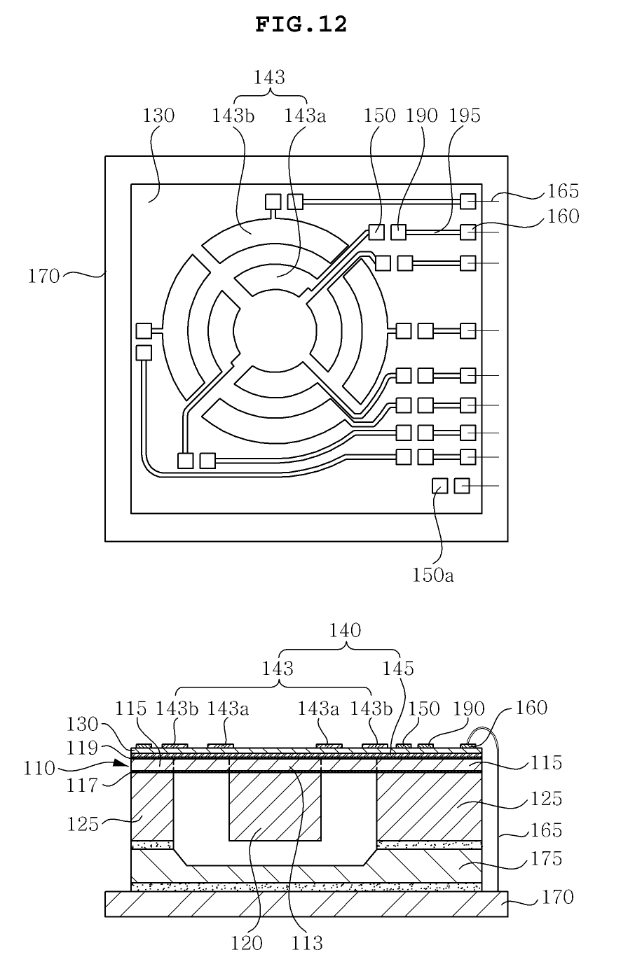

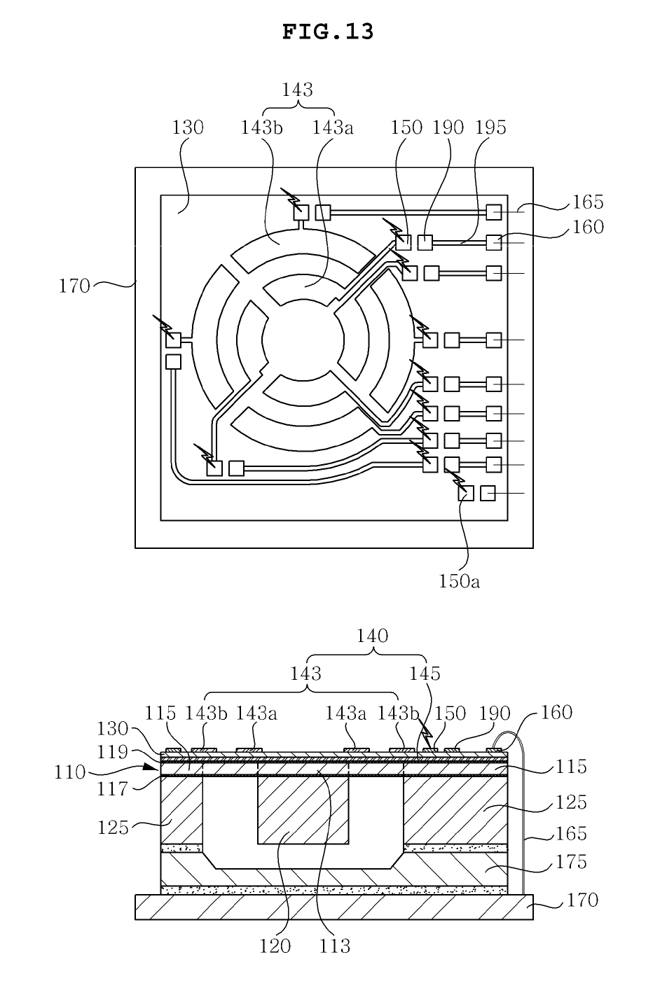

Next, as shown in FIGS. 12 and 13, alter the second pad 160 is electrically connected with the integrated circuit 170 (see FIG. 12), the process of poling the piezoelectric body 130 by applying voltage to the first pad 150 is performed (see FIG. 13). As described above, since the wire bonding is performed and then, the piezoelectric body 130 is poled, it is possible to previously prevent the piezoelectric deterioration phenomenon in the piezoelectric body 130 due to the high heat caused by the wire bonding. In addition, when poling the piezoelectric body 130, the first pad 150 applied with voltage is not electrically connected with the third pad 190 that is electrically connected with the integrated circuit 170. Therefore, even though voltage is applied to the first pad 150, the voltage is not applied to the integrated circuit 170 through the third pad 190 and the second pad 160, such that it is possible to prevent the elements in the integrated circuit 170 from being destructed.

Next, as shown in FIG. 14, a process of connecting the first pad 150 with the second pad 190 by the connection member 180 is performed. However, the first pad 150a electrically connected with the second electrode 145 does not have the corresponding third pad 190 and thus, the first pad 150a is electrically connected with the second pad 160 by the connection member 180. Meanwhile, the connection member 180 may be a conductive paste. As described above, when the first pad 150 is electrically connected with the third pad 190 or the second pad 160 by forming the connection member 180, finally, the integrated circuit 170 is electrically connected with the first electrode 143 or the second electrode 145, thereby driving the mass body 120 or sensing the displacement of the mass body 120.

The preferred embodiments of the present invention can prevent the elements in the integrated circuit from being destructed due to the high voltage applied at the time of the poling even when poling the piezoelectric body after connecting the integrated circuit, by separately providing the pads for poling the piezoelectric body in addition to the pad electrically connected with the integrated circuit.

In addition, the preferred embodiments of the present invention can prevent the poling from being released while the piezoelectric deterioration phenomenon occurring in the piezoelectric body due to the high heat caused by the wire bonding because of poling the piezoelectric body after connecting the integrated circuit with the inertial sensor by the wire bonding.

Although the preferred embodiments of the present invention have been disclosed for illustrative purposes, they are for specifically explaining the present invention and thus an inertial sensor and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, such modifications and alterations should also be understood to fall within the scope of the present invention. A specific protective scope of the present invention could be defined by the accompanying claims.

What is claimed is:

1. An inertial sensor, comprising:
a membrane;
a piezoelectric formed over the membrane;
an electrode formed on the piezoelectric body;
a first pad electrically connected with the electrode;
a second pad electrically connected with an integrated circuit; and
a connection member electrically connecting the first pad with the second pad.

2. The inertial sensor as set forth in claim 1, wherein the piezoelectric is poled by applying voltage to the first pad.

3. The inertial sensor as set forth in claim 1, wherein the second pad is electrically connected with the integrated circuit through a wire bonding.

4. The inertial sensor as set forth in claim 1, wherein the electrode includes:
a first electrode formed on one surface of the piezoelectric body; and
a second electrode formed on the other surface of the piezoelectric body.

5. The inertial sensor as set forth in claim 4, wherein the first pad is formed on one surface of the piezoelectric body, and
the first pad is electrically connected with the first electrode through a first wiring and is electrically connected with the second electrode through a via penetrating through the piezoelectric body.

6. The inertial sensor as set forth in claim 1, wherein the connection member is a conductive paste.

7. The inertial sensor as set forth in claim 1, further comprising a third pad electrically connected with the second pad through a second wiring,
wherein the connection member is a conductive paste electrically connecting the first pad with the third pad.

8. The inertial sensor as set forth in claim 4, wherein when the piezoelectric body is partitioned into an inner annular region surrounding a center of the piezoelectric body and an outer annular region surrounding the inner annular region, the first electrode includes:
driving electrodes patterned in an arc divided into N in the inner annular region; and
sensing electrodes patterned in an arc divided into M in the outer annular region.

9. The inertial sensor as set forth in claim 4, wherein when the piezoelectric body is partitioned into an inner annular region surrounding a center of the piezoelectric body and an outer annular region surrounding the inner annular region, the first electrode includes:
sensing electrodes patterned in an arc divided into N in the inner annular region; and
driving electrodes patterned in an arc divided into M in the outer annular region.

10. The inertial sensor as set forth in claim 1, further comprising:
a mass body provided under a central portion of the membrane; and
posts provided under edges of the membrane.

11. A method of manufacturing an inertial sensor, comprising:
(A) preparing a basic member including a membrane, a piezoelectric body formed over the membrane, an electrode formed on the piezoelectric body, and a first pad and a second pad electrically connected with the electrode;
(B) poling the piezoelectric body by applying voltage to the first pad after electrically connecting the second pad with an integrated circuit; and
(C) electrically connecting the first pad with the second pad by a connection member.

12. The method as set forth in claim 11, wherein at step (B), the second pad is electrically connected with the integrated circuit through a wire bonding

13. The method as set forth in claim 11, wherein at step (A), the electrode includes:
a first electrode formed on one surface of the piezoelectric body; and
a second electrode formed on the other surface of the piezoelectric body

14. The method as set forth in claim 13, wherein at step (A), the first pad is formed on one surface of the piezoelectric body, and
the first pad is electrically connected with the first electrode through a first wiring and is electrically connected with the second electrode through a via penetrating through the piezoelectric body.

15. The method as set forth in claim 11, wherein at step (C), the connection member is a conductive paste.

16. The method as set forth in claim 11, wherein at step (A), the basic member further includes a third pad electrically connected with the second pad through a second wiring, and
at step (C), the connection member is a conductive paste electrically connecting the first pad with the third pad.

17. The method as set forth in claim 13, wherein when the piezoelectric body is partitioned into an inner annular region surrounding a center of the piezoelectric body and an outer annular region surrounding the inner annular region, the first electrode includes:
driving electrodes patterned in an arc divided into N in the inner annular region; and
sensing electrodes patterned in an arc divided into M in the outer annular region.

18. The method as set forth in claim 13, wherein when the piezoelectric body is partitioned into an inner annular region surrounding a center of the piezoelectric body and an outer annular region surrounding the inner annular region, the first electrode includes:
sensing electrodes patterned in an arc divided into N in the inner annular region; and
driving electrodes patterned in an arc divided into M in the outer annular region.

19. The method as set forth in claim 11, wherein at step (A), the basic member includes:
a mass body provided under a central portion of the membrane; and
posts provided under edges of the membrane.
